(19) United States
(12) Patent Application Publication
(10) Pub. No.: US 2007/0120199 A1
(43) Pub. Date: May 31, 2007

(54) Low resistivity compound refractory metal silicides with high temperature stability

(75) Inventors: James Pan, Fishkill, NY (US); David Brown, Pleasant Valley, NY (US)

Correspondence Address: MCDERMOTT WILL & EMERY LLP, 600 13TH STREET, N.W., WASHINGTON, DC, 20005-3096, US

(73) Assignee: Advanced Micro Devices, Inc.

(21) Appl. No.: 11/289,680

(22) Filed: Nov. 30, 2005

(51) Int. Cl. H01L 29/76

(52) U.S. Cl. 257/377

(57) ABSTRACT

Compound refractory metal suicides are formulated to exhibit low resistivity and high temperature stability. Embodiments include various types of semiconductor devices comprising source/drain regions with a compound refractory metal silicide layer thereon, having a resistivity of 1 ohm.μ to 10 ohm.μ and stable at temperatures up to 1100° C.

### FIELD OF THE INVENTION

The present invention relates to semiconductor devices, particularly to self-aligned silicide (salicide) technology, and the resulting semiconductor devices. The present invention is particularly applicable to ultra large scale integrated circuit (ULSI) systems having features in the deep sub-micron regime exhibiting high thermal stability, increased operating speed and increased packing density.

### BACKGROUND ART

As integrated circuit geometries continue to plunge into the deep sub-micron regime, it becomes increasingly more difficult to accurately form discreet devices on a semiconductor substrate exhibiting the requisite reliability. High performance microprocessor applications require rapid speed of semiconductor circuitry. The speed of semiconductor circuitry varies inversely with the resistance (R) and capacitance (C) of the interconnection system. The higher the value of the R×C product, the more limiting the circuit operating speed. Miniaturization requires long interconnects having small contacts and small cross-sections. Accordingly, continuing reduction in design rules into the deep sub-micron regime requires decreasing the R and C associated with interconnection paths. Thus, low resistivity interconnection paths are critical to fabricating dense, high performance devices.

A common approach to reduce the resistivity of the interconnect to less than that exhibited by polysilicon alone, e.g., less than about 15-300 ohm/sq, comprises forming a multilayer structure consisting of a low resistance material, e.g., a refractory metal silicide, on a doped polycrystalline silicon layer, typically referred to as a polycide. Advantageously, the polycide gate/interconnect structure preserves the known work function of polycrystalline silicon and the highly reliable polycrystalline silicon/silicon oxide interface, since polycrystalline silicon is directly on the gate oxide.

As circuit density increases dramatically, multiple-level integrations become necessary, along with high temperature processing subsequent to metal silicide formation such as dopant activation. In replacement metal gate technology, the gate oxide is typically regrown at an elevated temperature, e.g., about 900° C. to about 1100° C., subsequent to silicide formation, thereby mandating the use of suicides having high thermal stability. Cobalt silicide, e.g., CoSi₂, is typically employed in salicide technology and exhibits thermal stability at temperatures up to about 700° C. to about 800° C. Nickel silicide is desirable because of its low thermal budget and ability to be formed in a single heating step at a relatively low temperature, e.g., about 250° C. to about 600° C., with an attendant reduction in substrate silicon consumption, thereby enabling the formation of ultra-shallow source/drain junctions. However, nickel silicide is stable at temperatures of only up to about 400° C. to about 500° C. Various refractory metal suicides, such as silicides of tungsten, (W), molybdenum (Mo), and tantalum (Ta), exhibit high temperature stability, as at a temperature above 1000° C. However, such refractory metal silicides exhibit a high resistivity which renders them unsuitable for use in logic source/drain transistors or memory cell applications.

Accordingly, there exists a need for a salicide methodology enabling the fabrication of various types of semiconductor devices having metal silicide layers which exhibit both low resistivity and high temperature thermal stability.

### DISCLOSURE OF THE INVENTION

An advantage of the present invention is a semiconductor device having metal silicide contacts on source/drain regions, wherein the metal silicide contacts exhibit both low resistivity and high thermal stability.

Additional advantages and other features of the present invention will be set forth in part in the description which follows, and in part will become apparent to those having ordinary skill in the art upon examination of the following or may be learned by practice of the present invention. The advantages of the present invention may be realized and obtained as particularly pointed out in the appended claims.

According to the present invention, the foregoing and other advantages are achieved in part by a semiconductor device comprising: a transistor having source/drain regions; and a compound refractory metal silicide layer on the source/drain regions, the compound refractory metal silicide comprising at least two refractory metals.

Embodiments of the present invention comprise semiconductor devices having compound refractory metal silicides which are stable at temperatures up to 1100° C. and exhibit a resistivity of 1 ohm.μ to 10 ohm.μ. Embodiments of the present invention include compound refractory metal silicides comprising silicon and two or more metals selected from the group consisting of Mo, platinum (Pt), Ta, W, rhenium (Re), titanium (Ti) and nickel (Ni). Embodiments of the present invention further include transistors formed on silicon-on-insulator (SOI) substrates with the compound refractory metal silicide layers formed on raised source/drain regions, and transistors formed by replacement metal gate techniques with the compound refractory metal silicides formed on the associated source/drain regions.

Additional advantages of the present invention will become readily apparent to those having ordinary skill in the art from the following detailed description, wherein embodiments of the present invention are described simply by way of illustration of the best mode contemplated for carrying out the present invention. As will be realized, the present invention is capable of other and different embodiments, and its several details are capable of modifications in various obvious respects, all without departing from the present invention. Accordingly, the drawings and description are to be regarded as illustrative in nature, and not as restrictive.

### BRIEF DESCRIPTION OF DRAWINGS

FIG. 1 schematically illustrates an embodiment of the present invention.

FIG. 2 schematically illustrates another embodiment of the present invention comprising a transistor with raised source/drain regions on an SOI substrate.

FIG. 3 schematically illustrates another embodiment of the present invention comprising a replacement metal gate transistor.

### DESCRIPTION OF THE INVENTION

The present invention addresses and solves problems attendant upon implementing conventional salicide technology to achieve large scale integration wherein thermal processing at elevated temperatures, as at about 1000° C. and higher, is implemented subsequent to salicide formation. Cobalt silicide and nickel silicide exhibit desirable resistivities, but are not stable at temperatures of about 900° C. to about 1100° C. Refractory metal silicides which do exhibit high thermal stability do not exhibit the requisite low resistivity. The present invention addresses and solves that problem by providing a methodology enabling the fabrication of metal silicide layers having both a low resistivity, e.g., about 1 ohmμ to about 10 ohm.μ while at the same time exhibiting a high thermal stability of about 900° C. to about 1100° C.

The present invention achieves the objective of providing metal silicide layers exhibiting both low resistivity and high thermal stability by forming compound, e.g., alloy, refractory metal silicides. By combining suitable refractory metals to form silicides, both high temperature stability and low resistivity can be achieved.

Embodiments of the present invention comprise forming metal silicides containing silicon and at least two refractory metals, such as Mo, Pt, Ta, W, Re, Co, Ti, Co, and Zr. Embodiments of the present invention include compound refractory metal silicides comprising two or more refractory metals, such as Mo, Pt, Ta, W, Re, combined with one metal, such as Ti, Mi, or Co. Suitable compound refractory metal silicides formulated to achieve low resistivity and high thermal stability include Ta—Ti—Si, W—Ti—Si, Pt-Mi-Ta—Si, Ni—Mo—Si and Co—Ta—Si.

Compound refractory metal silicides in accordance with the present invention may be deposited by co-sputtering separate metal layers followed by silicidation, or by forming an alloy of the selected metals and depositing a layer of the alloy followed by silicidation.

Embodiments of the present invention include forming compound refractory metal silicide layers on raised source/drain regions of transistors based on SOI substrates. Embodiments of the present invention enjoy particular applicability in replacement metal gate technology, wherein the gate oxide is regrown subsequent to silicide formation, as at a temperature of about 900° C. to about II 00° C., thereby mandating metal silicide layers having high thermal stability. The present invention also enables the fabrication of semiconductor devices employing high processing temperatures, such as temperatures in excess of 900° C., as for dopant activation and epitaxial silicon growth technology, without adversely impacting metal suicides formed on source/drain regions, thereby improving operating speed.

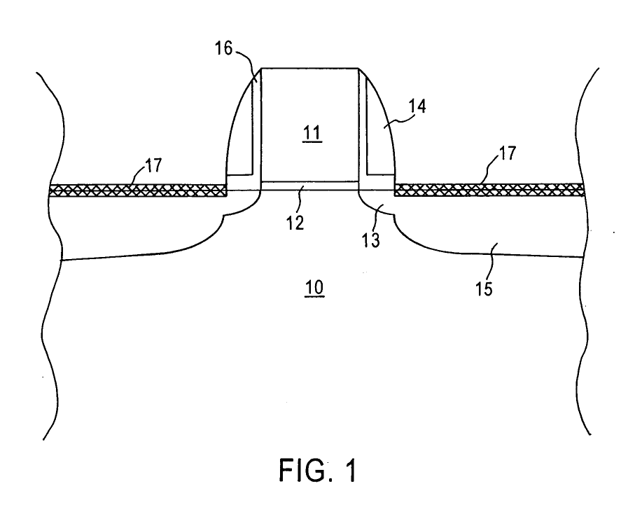

An embodiment of the present invention is schematically illustrated in FIG. 1 involving a typical MOSFET comprising gate electrode 11 formed on substrate 10 with a gate dielectric layer 12 therebetween. The transistor comprises shallow source/drain extensions 13, silicon nitride sidewall spacer, and optional silicon oxide liner 16 having an “L” shape to prevent silicide bridging. Reference character 15 denotes source/drain regions formed subsequent to spacer formation. Compound refractory metal silicide layer 17 is formed on the source/drain regions, as by co-sputtering different metals or by depositing an alloy of the selected metals followed by silicidation at an elevated temperature. Typically, the metal layers are deposited at thickness from 20 Å to 500 Å, e.g., 40 Å to 100 Å, and heating is conducted at temperatures of about 300° C. to about 1000° C., depending upon the particular alloy system formulated.

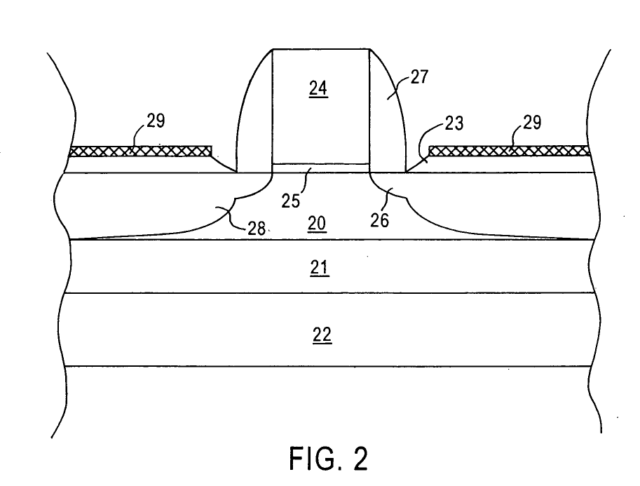

In another embodiment of the present invention illustrated in FIG. 2, a transistor is formed on a typical SOI substrate comprising semiconductor layer 20, insulating layer 21 and handle or substrate 22. Transistor gate electrode 24 is formed over the SOI substrate with gate dielectric layer 25 therebetween. Raised source/drain regions 23, typically epitaxially grown silicon, are formed on semiconductor layer 20. The transistor includes shallow source/drain extensions 26, dielectric sidewall spacers 27, and source/drain regions 28. Compound refractory metal silicide layers 29 are formed on raised source/drain regions 23.

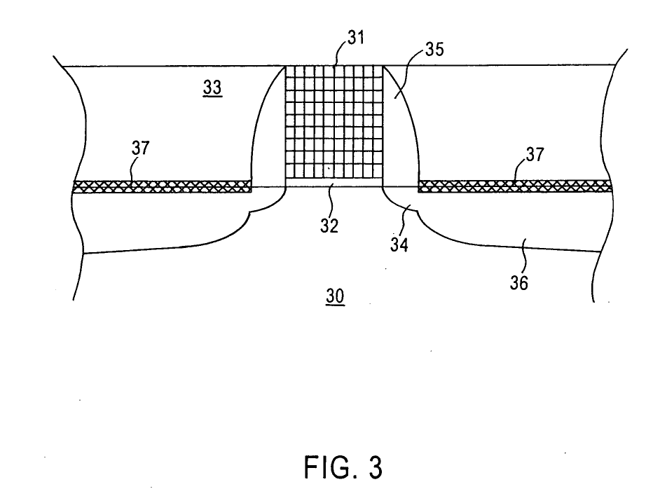

Another embodiment of the present invention is illustrated in FIG. 3 and comprises a transistor with a replacement metal gate 31 formed over substrate 30 with gate dielectric layer 32 therebetween. Substrate 30 can also include an SOI substrate. The illustrated transistor comprises shallow source/drain extensions 34, dielectric sidewall spacers 35 and source/drain regions 36. Reference character 33 denotes a dielectric layer formed during replacement metal gate implementation. Replacement metal gate electrode 31 may comprise tantalum nitride or a composite of tantalum nitride and another metal, such as copper (Cu), Ta or W. Compound refractory metal silicide layer 37 is formed on source/drain regions 36. In replacement metal gate technology, gate dielectric layer 32 is typically regrown subsequent to formation of the metal silicide layers. In accordance with embodiments of the present invention, compound refractory metal silicide layers 37 exhibit high thermal stability, thereby enabling regrowing of gate dielectric layer 32 without adversely impacting the integrity of the metal silicide layers and, hence, without sacrificing device speed. The optimum combination of metals for use in preparing compound refractory metal silicides in accordance with the present invention can be determined based upon the desired resistivity and high temperature thermal stability.

The present invention enables the fabrication of high density semiconductor devices with improved operating speed and improved reliability. The present invention enjoys industrial applicability in the fabrication of any various types of semiconductor devices by providing salicide technology enabling the fabrication of compound refractory metal silicides exhibiting high thermal stability and low resistivity.

In the preceding detailed description, the present invention is described with reference to specifically exemplary embodiments thereof. It will, however, be evident that various modifications and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A semiconductor device comprising:
a transistor having source/drain regions; and
a compound refractory metal silicide layer on the source/drain regions, the compound refractory metal silicide comprising at least two refractory metals.

2. The semiconductor device according to claim 1, wherein the compound refractory metal silicide is stable at temperatures up to 1100° C.

3. The semiconductor device according to claim 2, wherein the compound refractory metal silicide is stable over the entire temperature range of 900° C. to 1100° C.

4. The semiconductor device according to claim 3, wherein the compound refractory metal silicide is stable over the entire temperature range of 900° C. to 1000° C.

5. The semiconductor device according to claim 1, wherein the compound refractory metal silicide has a resistivity of 1 ohm.μ to 10 ohm.μ.

6. The semiconductor device according to claim 2, wherein the compound refractory metal silicide has a resistivity of 1 ohm.μ to 10 ohm.μ

7. The semiconductor device according to claim 6, wherein the refractory metal silicide comprises silicon and two or more metals selected from the group consisting of Zr, Mo, Pt, Ta, W, Re, Ti and Mi.

8. The semiconductor device according to claim 7, wherein the compound refractory metal silicide is selected from the group consisting of Ta—Ti—Si, W—Ti—Si, Pt—Ni—Ta—Si, Ni—Mo—Si, and Co—Ta—Si.

9. The semiconductor device according to claim 6, wherein the source/drain regions are raised source/drain regions.

10. The semiconductor device according to claim 9, wherein the transistor is formed on a silicon-on-insulator substrate.

11. The semiconductor device according to claim 6, wherein the transistor comprises a replacement metal gate electrode.

12. The semiconductor device according to claim 11, wherein the transistor is formed on a silicon-on-insulator substrate.
